(19) United States
(12) Patent Application Publication
(10) Pub. No.: US 2021/0114832 A1
(43) Pub. Date: Apr. 22, 2021

(54) ROLLER DEVICE FOR GUIDING A FLEXIBLE SUBSTRATE, USE OF A ROLLER DEVICE FOR TRANSPORTING A FLEXIBLE SUBSTRATE, VACUUM PROCESSING APPARATUS, AND METHOD OF PROCESSING A FLEXIBLE SUBSTRATE

(71) Applicant: Applied Materials, Inc., Santa Clara, CA (US)

(72) Inventors: Neil MORRISON, Darmstadt (DE); Uwe HERMANNS, Karlstein am Main (DE)

(21) Appl. No.: 17/251,683

(22) PCT Filed: Jun. 14, 2018
(86) PCT No.: PCT/EP2018/065849

§ 371 Date: Dec. 11, 2020

(51) Int. Cl. B65H 20/02; B65H 18/14; B65H 18/16

(52) U.S. Cl. CPC B65H 20/02; B65H 2404/18; B65H 18/16; B65H 18/145

(57) ABSTRACT

A roller device for guiding a flexible substrate is described. The roller device includes a support surface for contacting the flexible substrate, the support surface having a coating comprising an electronegative polymer. Further, a vacuum processing apparatus for processing a flexible substrate including the roller device and a method of processing a flexible substrate in the vacuum processing apparatus is described.

### TECHNICAL FIELD

Embodiments of the disclosure relate to rollers for guiding a flexible substrate. Further, embodiments of the disclosure relate to apparatuses and methods for flexible substrate processing, particularly flexible substrate coating with thin layers, using a roll-to-roll process. In particular, embodiments of the disclosure relate to rollers employed for transportation of a flexible substrate in apparatuses and methods for coating the flexible substrate with a stack of layers, e.g. for thin-film solar cell production, thin-film battery production, and flexible display production.

### BACKGROUND

Processing of flexible substrates, such as plastic films or foils, is in high demand in the packaging industry, semiconductor industries and other industries. In particular, roll-to-roll (R2R) processing of flexible substrates is of high interest due to high throughput at low costs. In particular, in the manufacture of thin film batteries, the display industry and the photovoltaic (PV) industry, roll-to-roll deposition systems are of high interest. For example, the increasing demand for flexible touch panel elements, flexible displays, and flexible PV modules result in an increasing demand for depositing suitable layers in R2R-coaters.

Processing may consist of coating a flexible substrate with a material, such as a metal, a semiconductor and a dielectric material, etching and other processing actions conducted on a substrate for the respective applications. For example, a coating process such as a CVD process or a PVD process, particularly a sputter process, can be utilized for depositing thin layers onto flexible substrates. Systems performing this task generally include a coating drum, e.g. a cylindrical roller, coupled to a processing system with a roller assembly for transporting the flexible substrate.

For achieving high quality coatings on flexible substrates, various challenges with respect to flexible substrate transportation have to be mastered. For example, providing an appropriate substrate tension as well as a good substrate-roller contact during processing the moving flexible substrate under vacuum conditions remain challenging.

Accordingly, there is a continuous demand for improving flexible substrate transportation in roll-to-roll processing systems, particularly for coating flexible substrates with high quality layers or layer stacks having improved uniformity, improved product lifetime, and a lower number of defects per surface area.

### SUMMARY

In light of the above, a roller device for guiding a flexible substrate, a use of a roller device for transporting a flexible substrate, a vacuum processing apparatus for processing a flexible substrate, and method of processing a flexible substrate in a vacuum processing apparatus according to the independent claims are provided. Further aspects, advantages, and features are apparent from the dependent claims, the description, and the accompanying drawings.

According to an aspect of the present disclosure, a roller device for guiding a flexible substrate is provided. The roller device includes a support surface for contacting the flexible substrate. The support surface has a coating including an electronegative polymer.

According to a further aspect of the present disclosure, a use of a roller device for transporting a flexible substrate in a vacuum processing apparatus is provided. The roller device includes a support surface for contacting the flexible substrate. The support surface has a coating including an electronegative polymer.

According to another aspect of the present disclosure, a vacuum processing apparatus for processing a flexible substrate is provided. The vacuum processing apparatus includes a first spool chamber housing a storage spool for providing the flexible substrate. Additionally, the vacuum processing apparatus includes a processing chamber arranged downstream from the first spool chamber. The processing chamber includes a plurality of processing units including at least one deposition unit. Further, the processing chamber includes a roller device for guiding the flexible substrate past the plurality of processing units. The roller device includes a support surface for contacting the flexible substrate. The support surface has a coating including an electronegative polymer. Additionally, the vacuum processing apparatus includes a second spool chamber arranged downstream from the processing chamber. The second spool chamber houses a wind-up spool for winding the flexible substrate thereon after processing.

According to a further aspect of the present disclosure, a method of processing a flexible substrate in a vacuum processing apparatus is provided. The method includes unwinding the flexible substrate from a storage spool provided in a first spool chamber. Additionally, the method includes processing the flexible substrate, while guiding the flexible substrate by a roller device provided in a processing chamber. The roller device includes a support surface for contacting the flexible substrate. The support surface has a coating including an electronegative polymer. Further, the method includes winding the flexible substrate on a wind-up spool provided in a second spool chamber after processing.

Embodiments are also directed at apparatuses for carrying out the disclosed methods and include apparatus parts for performing each described method aspect. These method aspects may be performed by way of hardware components, a computer programmed by appropriate software, by any combination of the two or in any other manner. Furthermore, embodiments according to the disclosure are also directed at methods for operating the described apparatus. The methods for operating the described apparatus include method aspects for carrying out every function of the apparatus.

### BRIEF DESCRIPTION OF THE DRAWINGS

So that the manner in which the above recited features of the present disclosure can be understood in detail, a more particular description of the disclosure, briefly summarized above, may be had by reference to embodiments. The accompanying drawings relate to embodiments of the disclosure and are described in the following:

FIG. 1 shows a schematic view of a roller device according to embodiments described herein;

FIG. 2 shows a schematic perspective view of a roller device according to further embodiments described herein;

FIG. 3 shows a schematic view of a vacuum processing apparatus according to embodiments described herein;

FIG. 4 shows a schematic view of a vacuum processing apparatus according to further embodiments described herein;

FIG. 5A shows a schematic side view of a vacuum processing apparatus having a set of evaporation crucibles;

FIG. 5B shows a schematic bottom view of the vacuum processing apparatus of FIG. 5A; and

FIGS. 6A and 6B show flowcharts for illustrating a method of processing a flexible substrate according to embodiments described herein.

### DETAILED DESCRIPTION OF EMBODIMENTS

Reference will now be made in detail to the various embodiments of the disclosure, one or more examples of which are illustrated in the figures. Within the following description of the drawings, the same reference numbers refer to same components. Only the differences with respect to individual embodiments are described. Each example is provided by way of explanation of the disclosure and is not meant as a limitation of the disclosure. Further, features illustrated or described as part of one embodiment can be used on or in conjunction with other embodiments to yield yet a further embodiment. It is intended that the description includes such modifications and variations.

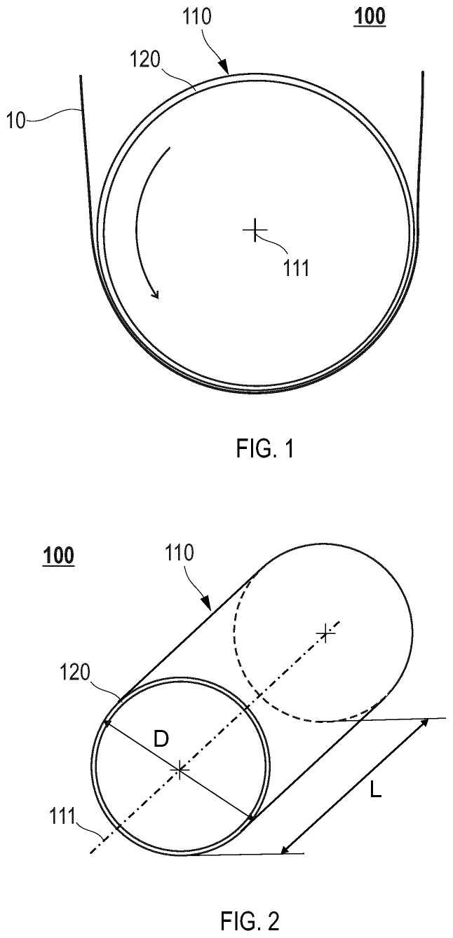

With exemplary reference to FIG. 1, a roller device 100 for guiding a flexible substrate 10 according to the present disclosure is described. According to embodiments, which can be combined with any other embodiments described herein, the roller device 100 includes a support surface 110 for contacting the flexible substrate 10. The support surface 110 has a coating 120 including an electronegative polymer.

Providing the roller device with a coating including an electronegative polymer beneficially provides for an improved contact of the flexible substrate with the roller device during flexible substrate transportation. Accordingly, embodiments of the roller device as described herein are improved compared to conventional rollers employed for guiding a flexible substrate, particularly in a roll-to-roll vacuum processing apparatus. More specifically, with the roller device as described herein, a substantially constant and homogenous contact force between the flexible substrate and the roller device can be achieved such that a clamping or adhesion of the flexible substrate to the roller device can be improved. The contact force may also be referred to as clamping force. Further, by employing a roller device having a coating as described herein, the heat transfer from the flexible substrate to the roller device can be improved compared to the state of the art, which can be beneficial for processing heat sensitive flexible substrates, particularly thin polymeric flexible substrates having a substrate width W of 0.3 m≤W≤8 m. The improved heat transfer results from the fact that during guiding the flexible substrate with the roller device of the present disclosure, a direct contact of the substrate with the coated support surface can be provided for substantially the complete contact surface, i.e. areas with gaps (down to the microscopic scale) between the flexible substrate and the coated support surface can be reduced or substantially be eliminated.

Further, it is to be noted that in the state of the art, typically the substrate tension is increased in order to improve the contact between the substrate and the substrate transport roller, which can cause some problems when thin flexible substrates are used, e.g. flexible substrates having a substrate thickness ST of 20 μm≤ST≤1 mm. In this regard, it is to be noted that the effective contact force or clamping force between the flexible substrate and the roller needs to be increased with increasing substrate width in order to compensate for the reduced effective substrate rigidity of thinner substrates.

Accordingly, embodiments of the roller device as described herein are beneficially well suited for guiding a polymeric flexible substrate having a substrate width W of 0.3 m≤W≤8 m and a substrate thickness ST of 20 μm≤ST≤1 mm.

Moreover, other conventional measures for improving the contact between the flexible substrate and a transport roller or guiding roller, such as providing an electrostatic charge to the substrate and/or to the transport roller/guiding roller, can be reduced or even omitted. In this regard, it is to be noted that providing an electrostatic charge to the substrate (e.g. by using a scalable linear electron beam source) and/or to the transport roller/guiding roller (e.g. by providing a DC voltage to the transport roller/guiding roller) can cause damage to the flexible substrate and/or to the roller surface, e.g. due to arcing during operation. Accordingly, beneficially with the roller device of the present disclosure, problems associated with conventional measures for improving the contact between the flexible substrate and a transport roller can substantially be reduced or even eliminated.

Before various further embodiments of the present disclosure are described in more detail, some aspects with respect to some terms used herein are explained.

In the present disclosure, a “roller device” can be understood as a drum or a roller having a substrate support surface for contacting the flexible substrate. In particular, the roller device can be rotatable about a rotation axis and may include a substrate guiding region. Typically, the substrate guiding region is a curved substrate support surface, e.g. a cylindrically symmetric surface, of the roller device. The curved substrate support surface of the roller device may be adapted to be (at least partly) in contact with the flexible substrate during the guiding of the flexible substrate. The substrate guiding region may be defined as an angular range of the roller device in which the substrate is in contact with the curved substrate surface during the guiding of the substrate, and may correspond to the enlacement angle of the roller device. In some embodiments, the enlacement angle of the roller device may be 120° or more, particularly 180° or more, or even 270° or more.

In the present disclosure, a “flexible substrate” can be understood as a bendable substrate. For instance, the “flexible substrate” can be a “foil” or a “web”. In the present disclosure, the term “flexible substrate” and the term “substrate” may be synonymously used. For example, the flexible substrate as described herein may include materials like PET, HC-PET, PE, PI, PU, TaC, OPP, BOOP, CPP, one or more metals, paper, combinations thereof, and already coated substrates like Hard Coated PET (e.g. HC-PET, HC-TaC) and the like. In some embodiments, the flexible substrate is a COP substrate provided with an index matched (IM) layer on both sides thereof. For example, the substrate thickness can be 1 μm or more and 200 μm or less. More specifically, the substrate thickness can be selected from the range of having a lower limit of 8 μm and an upper limit of 25 μm, for instance for food packaging applications.

In the present disclosure, the expression “support surface for contacting the flexible substrate” can be understood as the outer surface of the roller device configured for contacting the flexible substrate during the guiding or the transporting of the flexible substrate. Typically, the support surface is a curved outer surface, particularly a cylindrical outer surface, of the roller device.

In the present disclosure, the expression “support surface having a coating” can be understood in that the support surface of the roller device includes a coating, i.e. the support surface is coated. In particular, the coating includes an electronegative polymer. An “electronegative polymer” may be understood as a polymer having electronegative properties. Typically, the coating is provided on the complete support surface. In particular, the coating has a constant thickness, e.g. a thickness T selected from the range of 2.5 μm≤T≤15 μm.

According to some embodiments, which can be combined with other embodiments described herein, the coating 120 has triboelectric properties. In other words, the electronegative polymer can be configured to generate static charge through fictional contact with the flexible substrate. In particular, the electronegative polymer (e.g. a fluoropolymer) can be configured to create a mirror charge on the flexible substrate surface during guiding through the triboelectric effect. The triboelectric effect (also known as triboelectric charging) is a type of contact electrification on which certain materials become electrically charged after coming into fictional contact with a different material. In other words, the triboelectric effect can be described as the transfer of charge (electrons) from one material to another following friction or sliding contact. The total charge transfer between two materials is defined by the difference of charge affinity between the two contacting material surfaces.

For instance, substrate materials as described herein have a charge affinity CA of −90 nC/J≤CA≤−40 nC/J. For instance, PET has a charge affinity CA of CA≈−40 nC/J, BOOP has a charge affinity CA of CA≈−85 nC/J, and LDEP, HDPE and PP have charge affinities CA of CA≈−90 nC/J. The coating comprising an electronegative polymer as described herein, particularly comprising or consisting of a fluoropolymer, particularly comprising or consisting of PTFE and/or PFA, has a charge affinity CA of CA≈−190 nC/J.

Accordingly, beneficially the coating provided on the support surface of the roller device as described herein ensures that the coated roller device is negatively charged compared with the substrate, even in the absence of an externally applied electric field. Accordingly, it is to be understood that according to embodiments which can be combined with other embodiments herein, the coating on the support surface of the roller device can be configured to provide for a charge affinity difference ΔCA with respect to the flexible substrate to be guided by the roller device. In particular, the charge affinity difference ΔCA between the coating and the substrate can be 50 nC/J≤ΔCA≤200 nC/J, particularly 100 nC/J≤ΔCA≤150 nC/J.

As outlined above, in the embodiments of the roller device as described herein, the coating of electronegative polymers provided on the support surface of the roller device can be configured for providing a contact electrification with the flexible substrate during the guiding of the flexible substrate. Typically, the flexible substrate is guided by rotating the roller device 100 around a rotation axis 111 of the roller device, as exemplarily indicated by the arrow in FIG. 1. For instance, the roller device may be actively driven. In other words, a drive may be provided for rotating the roller device.

Accordingly, providing a coating comprising an electronegative polymer on the support surface of the roller device configured for creating a mirror charge on the flexible substrate surface being in contact with the role device during substrate guiding, beneficially provides for improving the adhesion of the flexible substrates to the roller device. In other words, providing a coating having triboelectric properties on the support surface of the roller device, beneficially provides for a charge transfer between the coating and the flexible substrate such that a constant and homogenous contact force (also referred to as pinning force or clamping force) between the flexible substrate and the roller device can be ensured. Further, exploiting the triboelectric effect beneficially provides for a slip reduction between the flexible substrate and the coating provided on the support surface of the roller device.

According to some embodiments, which can be combined with other embodiments described herein, the electronegative polymer can be dielectric. In particular, the electronegative polymer can be an electrical insulating material which can be polarized. For instance, the electronegative polymer can be a fluoropolymer, particularly an elastomeric fluoropolymer, e.g. comprising perfluoralkoxy-polymere (PFA) and/or a polytetrafluorethylen (PTFE). In particular, the fluoropolymer may consist of PFA or PTFE. A coating comprising or consisting of a fluoropolymer, such as PFA or PTFE, beneficially provides for a coating having a very high dielectric breakdown strength. Further, a coating comprising or consisting of a fluoropolymer, such as PFA or PTFE, beneficially provides for a low friction coefficient, particularly an ultra-low friction coefficient. Accordingly, beneficially low wear rates of the coating, e.g. comparable to steels, can be provided ensuring coating longevity. In other words, a fluoropolymer coating providing a fluorinated polymer coating surface beneficially provides for an excellent low frictional performance level reducing effective coating wear.

According to some embodiments, which can be combined with other embodiments described herein, the coating 120 can have a friction coefficient μ of μ≤0.1, particularly a friction coefficient μ of μ≤0.05. More specifically, a non-lubricated fluoropolymer friction coefficient μ can be μ≤0.1, particularly μ≤0.05. It is to be noted that partial wear from coating asperities can provide highly hydrophobic hydrodynamic boundary lubrication, beneficially further reducing the friction coefficient by a factor F of approximately F=10. Accordingly, beneficially an effective coating material wear rate approaching the intrinsic wear rate level of steel can be achieved.

For instance, according to some embodiments, which can be combined with other embodiments described herein, the coating 120 may have a wear-rate constant kₐ of 0.4×10⁻⁷ MPa⁻¹≤kₐ≤2.0×10⁻⁶ MPa-1. In other words, the coating may be configured to have a wear-rate constant kₐ selected from the range of 0.4×10⁻⁷ MPa⁻¹≤kₐ≤2.0×10⁻⁶ MPa⁻¹. The wear rate constant kₐ is the dimensionless wear rate constant k divided by the hardness [MPa], i.e. kₐ [MPa⁻¹]=k/hardness [MPa].

According to some embodiments, which can be combined with other embodiments described herein, the coating 120 can have a thickness T of 2.5 μm≤T≤15 μm. Providing a coating having a thickness T selected from the range of 2.5 μm≤T≤15 μm can be beneficial to ensure sufficient capacitance to ensure a sufficient pinning force between the flexible substrate and the coated support surface of the roller device.

According to some embodiments, which can be combined with other embodiments described herein, the coating 120 has a breakdown field strength BFS of 2.0 MV/cm≤BFS≤30 MV/cm. For instance, a coating of PFA having a thickness T of T=5 μm has a BFS of 2.0 MV/cm when an electrical field of 300V is applied. A coating of PTFE having a thickness T of T=10 μm has a BFS of 24 MV/cm when an electrical field of 300V is applied

With exemplary reference to FIG. 2, according to some embodiments which can be combined with other embodiments described herein, the roller device 100 is cylindrical and has a length L of 0.5 m≤L≤8.5 m. Further, the roller device 100 may have a diameter D of 1.0 m≤D≤3.0 m. Accordingly, beneficially the roller device is configured for guiding and transporting flexible substrates having a large width.

According to some embodiments, which can be combined with other embodiments described herein, the roller device may have one or more E-chuck devices (not explicitly shown). An E-chuck device can be understood as a device configured for providing an electrostatic charge for holding a substrate by electrostatic force. In particular, the one or more E-chuck devices may hold the flexible substrate and/or provide an attraction force for holding the web in contact with the curved surface of the roller device. Accordingly, a constant and homogenous contact force between the flexible substrate and the roller device may be further improved.

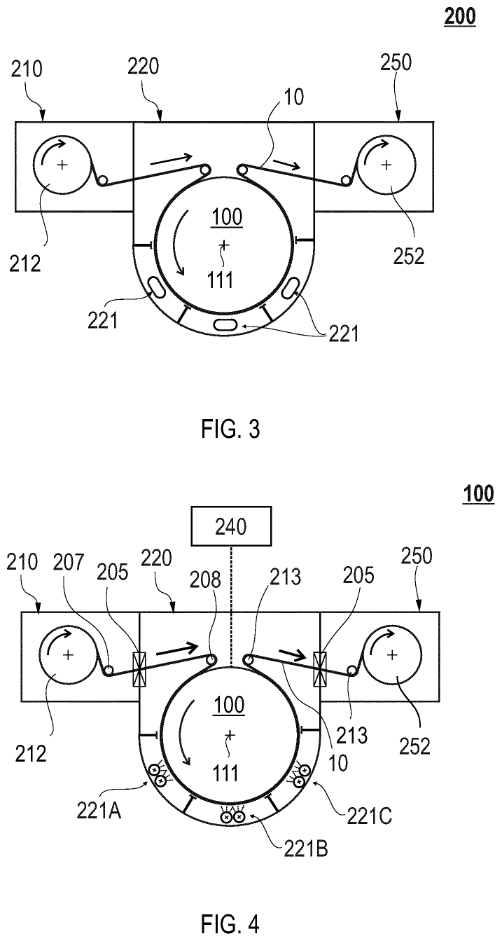

In view of the above, it is to be understood that according to a further aspect of the present disclosure, a use of a roller device according to any embodiments described herein for transporting a flexible substrate in a vacuum processing apparatus, particularly a vacuum processing apparatus according to embodiments as described with reference to FIGS. 3 and 4, is provided.

With exemplary reference to FIG. 3, a vacuum processing apparatus 200 according to the present disclosure is described. According to embodiments, which can be combined with any other embodiments described herein, the vacuum processing apparatus 200 includes a first spool chamber 210 housing a storage spool 212 for providing the flexible substrate 10. Additionally, the vacuum processing apparatus 200 includes a processing chamber 220 arranged downstream from the first spool chamber 210. The processing chamber 220 includes a plurality of processing units 221. The plurality of processing units 221 include at least one deposition unit. For example, the plurality of processing units may be arranged in a circumferential direction around the roller device 100, as schematically illustrated in FIGS. 3 and 4. As the roller device 100 rotates, the flexible substrate is guided past the processing units which face toward the curved substrate support surface of the roller device, so that the surface of the flexible substrate can be processed while being moved past the processing units at a predetermined speed. For example, the plurality of processing units may include one or more units selected from the group consisting of: a deposition unit, an etching unit, and a heating unit. A deposition unit of the vacuum processing apparatus as described herein can be a sputter deposition unit, e.g. an AC (alternating current) sputter source or a DC (direct current) sputter source, a CVD deposition unit, a PECVD deposition unit or a PVD deposition unit.

Further, the processing chamber 220 includes a roller device 100 for guiding the flexible substrate past the plurality of processing units 221. The roller device 100 includes a support surface 110 for contacting the flexible substrate 10. The support surface 110 has a coating 120 including an electronegative polymer. In particular, the roller device is a roller device according to any embodiments described herein. Additionally, the vacuum processing apparatus 200 includes a second spool chamber 250 arranged downstream from the processing chamber 220. The second spool chamber 250 houses a wind-up spool 252 for winding the flexible substrate 10 thereon after processing.

Accordingly, embodiments of the vacuum processing apparatus as described herein are improved compared to conventional vacuum processing apparatuses. In particular, by providing a vacuum processing apparatus with a roller device as described herein beneficially provides for improved flexible substrate guiding and transportation. More specifically, guiding and transportation of the flexible substrate can be improved because the roller device as described herein provides for a substantially constant and homogenous contact force between the flexible substrate and the roller device, such that a clamping or adhesion of the flexible substrate to the roller device can be improved. Accordingly, beneficially substantially wrinkle-free flexible substrate transportation can be ensured resulting in higher quality processing results, e.g. coatings of higher quality on the flexible substrate.

In the present disclosure, a “vacuum processing apparatus” can be understood as an apparatus configured for processing a substrate, particularly a flexible substrate as described herein. In particular, the vacuum processing apparatus may be a roll-to-roll (R2R) processing apparatus configured for coating a flexible substrate with a stack of layers. Typically, the vacuum processing apparatus has at least one vacuum chamber, particularly a vacuum processing chamber. Further, the processing apparatus may be configured for a substrate length of 500 m or more, 1000 m or more, or several kilometres. The substrate width can be 300 mm or more, particularly 500 mm or more, more particularly 1 m or more. Further, the substrate width can be 8 m or less, particularly 6 m or less.

In the present disclosure, a “processing chamber” can be understood as a chamber having at least one deposition unit for depositing material on a substrate. Accordingly, the processing chamber may also be referred to as deposition chamber. The term “vacuum”, as used herein, can be understood in the sense of a technical vacuum having a vacuum pressure of less than, for example, 10 mbar. Typically, the pressure in a vacuum chamber as described herein may be between 10⁻⁵ mbar and about 10⁻⁸ mbar, more typically between 10⁻⁵ mbar and 10⁻⁷ mbar, and even more typically between about 10⁻⁶ mbar and about 10⁻⁷ mbar.

The terms “upstream from” and “downstream from” as used herein may refer to the position of the respective chamber or of the respective component with respect to another chamber or component along the substrate transportation path. For example, during operation, the substrate is guided from the first spool chamber 210 through the processing chamber 220 and subsequently guided to the second spool chamber 250 along the substrate transportation path via a roller assembly. Accordingly, the processing chamber 220 is arranged downstream from the first spool chamber 210, and the first spool chamber 210 is arranged upstream from the processing chamber 220. When, during operation, the substrate is first guided by or transported past a first roller or a first component and subsequently guided by or transported past a second roller or a second component, the second roller or second component is arranged downstream from the first roller or first component.

As exemplarily shown in FIGS. 3 and 4, the first spool chamber 210 is typically configured to accommodate a storage spool 212, wherein the storage spool 212 may be provided with the flexible substrate 10 wound thereon. During operation, the flexible substrate 10 can be unwound from the storage spool 212 and transported along the substrate transportation path (indicated by the arrows in FIGS. 3 and 4) from the first spool chamber 210 toward the processing chamber 220. The term “storage spool” as used herein may be understood as a roll on which a flexible substrate to be coated is stored. Accordingly, the term “wind-up spool” as used herein may be understood as a roll adapted for receiving the coated flexible substrate. The term “storage spool” may also be referred to as a “supply roll”, and the term “wind-up spool” may also be referred to as a “take-up roll”.

In the present disclosure, a “processing unit” can be understood as a unit or device configured for processing a flexible substrate as described herein. For example, the processing unit may be a deposition unit. In particular, the deposition unit may be a sputter deposition unit, e.g. an AC sputter source or a DC sputter source. However, the processing apparatus described herein is not limited to sputter deposition, and other deposition units may additionally or alternatively be used. For example, in some implementations, CVD deposition units, evaporation deposition units, PECVD deposition units or other deposition units may be utilized. Accordingly, it is to be understood that the deposition units, e.g. a plasma deposition source, can be adapted for depositing a thin film on a flexible substrate, e.g., to form a flexible display device, a touch-screen device component, or other electronic or optical devices.

According to some embodiments, which can be combined with other embodiments described herein, the roller device 100 of the vacuum processing apparatus is a processing drum. In the present disclosure, a “processing drum” can be understood as a drum or a roller having a substrate support surface for contacting the flexible substrate during processing. In particular, the processing drum can be rotatable about a rotation axis 111 and may include a substrate guiding region. Typically, the substrate guiding region is a curved substrate support surface, e.g. a cylindrically symmetric surface, of the processing drum. The curved substrate support surface of the processing drum may be adapted to be (at least partly) in contact with the flexible substrate during the operation of the processing apparatus as described herein.

In particular, with exemplary reference to FIG. 4, the roller device 100 can be connected to a device 240 for applying an electrical potential to the processing drum, the processing drum being a roller device 100 according to any embodiments descried herein.

In the present disclosure, a “device for applying an electrical potential to the processing drum” can be understood as a device being configured to apply an electrical potential to the processing drum, particularly to the substrate support surface of the processing drum. In particular, the device for applying an electrical potential can be configured to provide a middle frequency (MF) electrical potential. For instance, the middle frequency (MF) electrical potential can be from 1 kHz to 100 kHz. In the present disclosure, the “device for applying an electrical potential” may also be referred to as “electrical potential application device”. Applying a MF electrical potential to the processing drum has the advantage that a charge up of the substrate, particularly of the layer deposited on the substrate, can substantially be avoided or even eliminated. Accordingly, layers with higher quality (e.g. higher uniformity, less defects, etc.) can be deposited on the substrate. Accordingly, providing an electrical potential application device can be beneficial for further improving constant and homogenous contact force between the flexible substrate and the roller device resulting in improved substantially wrinkle-free flexible substrate transportation during substrate processing.

With exemplary reference to FIGS. 3 and 4, it is to be understood that typically the vacuum processing apparatus 200 is configured such that the flexible substrate 10 can be guided from the first spool chamber 210 to the second spool chamber 250 along a substrate transportation path, wherein the substrate transportation path may lead through the processing chamber 220. For example, the flexible substrate can be coated with a stack of layers in the deposition chamber. Further, as exemplarily shown in FIGS. 3 and 4, a roller assembly comprising a plurality of rolls or rollers can be provided for transporting the substrate along the substrate transportation path. In FIGS. 3 and 4, a roller assembly comprising four rollers is shown. It is to be understood that, according to different configurations, the roller assembly may include five or more rollers, particularly ten or more rollers, arranged between the storage spool and the wind-up spool.

With exemplary reference to FIGS. 3 and 4, according to some embodiments herein, which can be combined with any other embodiments described herein, the roller assembly may be configured to transport the flexible substrate along a partially convex and partially concave substrate transportation path from the first spool chamber to the second spool chamber. In other words, the substrate transportation path may be partially curved to the right and partially curved to the left, such that some guiding rollers contact a first main surface of the flexible substrate and some guiding rollers contact a second main surface of the flexible substrate opposite the first main surface.

For example, the first guiding roller 207 in FIG. 4 contacts a second main surface of the flexible substrate, and the flexible substrate is bent to the left while being guided by the first guiding roller 207 (“convex” section of the substrate transportation path). The second guiding roller 208 in FIG. 4 contacts a first main surface of the flexible substrate, and the flexible substrate is bent to the right while being guided by the second guiding roller 208 (“concave” section of the substrate transportation path).

In some embodiments, one or more rollers, e.g. guiding rollers, of the roller assembly may be arranged between the storage spool 212 and the processing drum, i.e. the roller device 100, and/or downstream from the processing drum. For example, in the embodiment shown in FIG. 3, two guiding rollers are provided between the storage spool 212 and the processing drum, wherein at least one guiding roller may be arranged in the first spool chamber and at least one guiding roller may be arranged in the processing chamber upstream from the processing drum. In some embodiments, three, four, five or more, particularly eight or more guiding rollers are provided between the storage spool and the processing drum. The guiding rollers may be active or passive rollers.

An “active” roller or roll as used herein may be understood as a roller that is provided with a drive or a motor for actively moving or rotating the respective roller. For example, an active roller may be adjusted to provide a predetermined torque or a predetermined rotational speed. Typically, the storage spool 212 and the wind-up spool 252 may be provided as active rollers. Further, active rollers can be configured as substrate tensioning rollers configured for tensioning the substrate with a predetermined tensioning force during operation. A “passive” roller may be understood as a roller or roll that is not provided with a drive for actively moving or rotating the passive roller. The passive roller may be rotated by the frictional force of the flexible substrate that may be in direct contact with an outer roller surface during operation.

As exemplarily shown in FIG. 4, one or more guiding rollers 213 may be arranged downstream from the processing drum, i.e. the roller device 100, and upstream from the second spool chamber 250. For example, at least one guiding roller may be arranged in the processing chamber 220 downstream from the processing drum for guiding the flexible substrate 10 toward the second spool chamber 250, arranged downstream from the processing chamber 220, or at least one guiding roller may be arranged in the second spool chamber 250 upstream from the processing drum for guiding the flexible roller in a direction essentially tangential to the substrate support surface of the processing drum, in order to smoothly guide the flexible substrate onto the wind-up spool 252.

According to some embodiments, which can be combined with other embodiments described herein, one or more guiding rollers of the roller assembly may include a coating including an electronegative polymer, as exemplarily described for the roller device according to any embodiments described herein.

According to some embodiments, some chambers or all chambers of the vacuum processing apparatus 200 may be configured as vacuum chambers that can be evacuated. For instance, the vacuum processing apparatus may include components and equipment allowing for the generation of or maintenance of a vacuum in the first spool chamber 210 and/or the processing chamber 220 and/or the second spool chamber 250. In particular, the vacuum processing apparatus may include vacuum pumps, evacuation ducts, vacuum seals and the like for generating or maintaining a vacuum in the first spool chamber 210 and/or the processing chamber 220 and/or the second spool chamber 250.

With exemplary reference to FIG. 4, according to embodiments which can be combined with other embodiments described herein, sealing devices 205 may be provided between adjacent chambers, e.g. between the first spool chamber 210 and the processing chamber 220 and/or between the processing chamber 220 and the second spool chamber 250. Accordingly, beneficially the winding chambers (i.e. the first spool chamber 210 and the second spool chamber 250) may be vented or evacuated independently, in particular independently from the processing chamber. The sealing device 205 may include an inflatable seal configured to press the substrate against a flat sealing surface.

As exemplarily shown in FIG. 4, typically the processing drum, i.e. the roller device as described herein, is configured for guiding the flexible substrate 10 past the plurality of deposition units, e.g. past a first deposition unit 221A, a second deposition unit 221B, and a third deposition unit 221C. As shown in FIG. 4, the individual deposition units may be provided in separate compartments which allows for a modular combination of several different subsequent deposition processes (e.g. CVD, PECVD and/or PVD) and ensures very good gas separation between the different subsequent deposition processes. Accordingly, dependent from the selected sequence of deposition units, various different stack layers can be deposited on the flexible substrate.

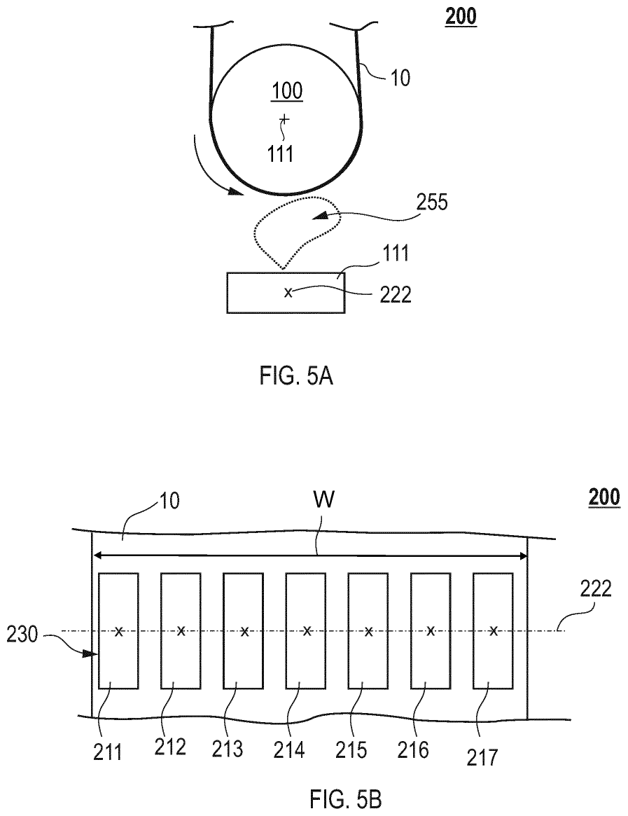

FIG. 5A shows a schematic side view of a processing apparatus according to an alternative configuration and FIG. 5B shows a schematic bottom view of the processing apparatus shown in FIG. 5A. In particular, with exemplary reference to FIGS. 5A and 5B, the plurality of processing units can include or be configured as a set 230 of evaporation crucibles aligned along a line 222 extending parallel to the rotation axis 111 of the roller device 100. Accordingly, the vacuum processing apparatus may be an evaporation apparatus for depositing evaporated material on the substrate 10. For example, the set 230 of evaporation crucibles shown in FIG. 5A includes crucibles 211 to 217. As exemplarily shown in FIG. 5B, the evaporation crucibles are typically configured for generating a cloud 255 of evaporated material to be deposited on the flexible substrate 10. As shown in FIG. 5B, the plurality of processing units may be arranged in a direction across the substrate width W.

An “evaporation crucible” can be understood as a reservoir for the material to be evaporated by heating the evaporation crucible. More specifically, an evaporation crucible may be equipped with a material supply for delivering the material to be evaporated to the crucibles. For example, the material to be evaporated may be supplied to the evaporation crucible in the form of a wire which may be melted by the evaporation crucible. According to some embodiments, the evaporation crucible may be configured as an evaporator boat, particularly when the material to be evaporated is supplied in the form of a wire. Accordingly, a set of evaporation crucibles as described herein can be a set of evaporator boats. The material to be evaporated can be a metal, for example aluminum, copper or any other metal. The processing apparatus as exemplarily described with reference to FIGS. 5A and 5B, is particularly well suited for coating substrates used in the packaging industry, particularly the food packing industry.

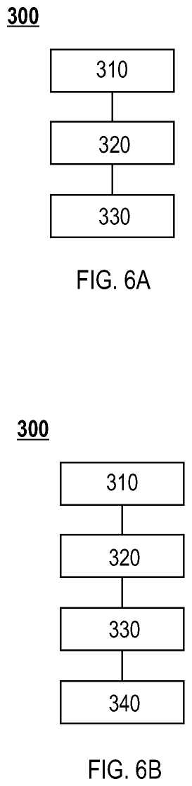

With exemplary reference to the flowchart shown in FIG. 6A, a method 300 of processing a flexible substrate 10 in a vacuum processing apparatus 200 according to the present disclosure is described. According to embodiments, which can be combined with any other embodiments described herein, the method includes unwinding (represented by block 310 in FIG. 6A) the flexible substrate 10 from a storage spool 212 provided in a first spool chamber 210. Additionally, the method includes processing (represented by block 320 in FIG. 6A) the flexible substrate 10, while guiding the flexible substrate by a roller device 100 provided in a processing chamber 220. The roller device 100 includes a support surface 110 for contacting the flexible substrate 10. The support surface 110 has a coating 120 including an electronegative polymer. In particular, the roller device 100 can be a roller device according to any embodiments described herein. Further, the method includes winding (represented by block 330 in FIG. 6A) the flexible substrate on a wind-up spool 252 provided in a second spool chamber 250 after processing.

With exemplary reference to FIG. 6B, according to some embodiments, which can be combined with other embodiments described herein, the method further includes applying (represented by block 340 FIG. 6B) an electrical potential to the roller device 100. For instance, applying (block 340) the electrical potential to the roller device may include applying a middle frequency potential having a frequency of 1 kHz to 100 kHz. In particular, applying the electrical potential to the roller device 100 typically includes using a device 240 for applying an electrical potential, e.g. as described with reference to FIG. 4.

Further, it is to be understood that the method of processing a flexible substrate in a vacuum processing apparatus may be conducted by using a vacuum processing apparatus 200 according to any embodiments described herein, e.g. with reference to FIGS. 3 and 4.

In view of the above, it is to be understood that compared to the state of the art, embodiments as described herein provide for improved flexible substrate transportation in roll-to-roll processing apparatuses, such that beneficially thinner and wider flexible substrates can be processed and the processing result can be improved.

While the foregoing is directed to embodiments, other and further embodiments may be devised without departing from the basic scope, and the scope is determined by the claims that follow.

1. A roller device for guiding a flexible substrate, the roller device comprising a support surface for contacting the flexible substrate, the support surface having a coating comprising an electronegative polymer.

2. The roller device of claim 1, the coating having triboelectric properties.

3. The roller device of claim 1, the electronegative polymer being dielectric.

4. The roller device of claim 1, the coating having a friction coefficient μ of μ≤0.1.

5. The roller device (100) of claim 1, the coating having a wear-rate constant kₐ of 0.4×10⁻⁷ MPa⁻¹≤kₐ≤2.0×10⁻⁶ MPa⁻¹.

6. The roller device of claim 1, the coating having a thickness T of 2.5 μm≤T≤15 μm.

7. The roller device of claim 1, the coating having a breakdown field strength BFS of 2.0 MV/cm≤BFS≤30 MV/cm.

8. The roller device of claim 1, the electronegative polymer being a fluoropolymer, particularly perfluoralkoxy-polymere (PFA) or polytetrafluorethylen (PTFE).

9. The roller device of claim 1, the roller device being cylindrical having a length L of 0.5 m≤L≤5.0 m.

10. The roller device of claim 1, the roller device having a diameter D of 1.0 m≤D≤3.0 m.

11. Use of a roller device for transporting a flexible substrate in a vacuum processing apparatus, the roller device comprising a support surface for contacting the flexible substrate, the support surface having a coating comprising an electronegative polymer.

12. A vacuum processing apparatus for processing a flexible substrate, comprising:
a first spool chamber housing a storage spool for providing the flexible substrate;
a processing chamber arranged downstream from the first spool chamber, the processing chamber comprising a plurality of processing units comprising at least one deposition unit and a roller device for guiding the flexible substrate past the plurality of processing units, the roller device comprising a support surface for contacting the flexible substrate, the support surface having a coating comprising an electronegative polymer; and
a second spool chamber arranged downstream from the processing chamber and housing a wind-up spool for winding the flexible substrate thereon after processing.

13. The vacuum processing apparatus of claim 12, wherein the roller device is a processing drum, the processing drum being connected to a device for applying an electrical potential to the processing drum.

14. A method of processing a flexible substrate in a vacuum processing apparatus, the method comprising:
unwinding the flexible substrate from a storage spool provided in a first spool chamber;
processing the flexible substrate, while guiding the flexible substrate by a roller device provided in a processing chamber, the roller device comprising a support surface or contacting the flexible substrate, the support surface having a coating comprising an electronegative polymer; and
winding the flexible substrate on a wind-up spool provided in a second spool chamber after processing.

15. The method of claim 14, further comprising applying an electrical potential to the roller device.

16. The roller device of claim 2, the electronegative polymer being dielectric.

17. The roller device of claim 2, the coating having a friction coefficient μ of μ≤0.1.

18. The roller device of claim 3, the coating having a friction coefficient μ of μ≤0.1.

19. The roller device of claim 1, the electronegative being perfluoralkoxy-polymere (PFA).

20. The roller device of claim 1, the electronegative being polytetrafluorethylen (PTFE).
